(19) United States
(12) Patent Application Publication
(10) Pub. No.: US 2017/0364306 A1
(43) Pub. Date: Dec. 21, 2017

(54) ELECTRONIC DEVICE AND METHOD FOR FABRICATING THE SAME

(71) Applicant: SK hynix Inc., Icheon (KR)

(72) Inventor: In-Hoe KIM, Seoul (KR)

(21) Appl. No.: 15/441,080

(22) Filed: Feb. 23, 2017

(30) Foreign Application Priority Data
Jun. 17, 2016 (KR) 10-2016-0075630

(51) Int. Cl. G06F 3/06; H01L 43/12; H01L 43/10; G06F 12/0802; H01L 43/02; H01L 27/24; H01L 27/22; G06F 13/40; H01L 45/00; H01L 43/08

(52) U.S. Cl. CPC G06F 3/0659; H01L 45/1675; G06F 3/0602; H01L 45/147; H01L 45/146; H01L 45/144; H01L 45/143; H01L 45/1253; H01L 45/1233; H01L 43/12; H01L 43/10; H01L 43/08; H01L 43/02; H01L 27/2463; H01L 27/2427; H01L 27/2418; H01L 27/224; G06F 13/4068; G06F 12/0802; G06F 3/0685; G06F 3/0661; H01L 45/1608

(57) ABSTRACT

A method for fabricating an electronic device including a semiconductor memory includes: forming a memory layer over a substrate; forming a memory element by selectively etching the memory layer, wherein forming the memory element includes forming an etching residue on a sidewall of the memory element, the etching residue including a first metal; and forming a spacer by implanting oxygen and a second metal into the etching residue, the spacer including a compound of the first metal-oxygen-the second metal, the second metal being different from the first metal.

### CROSS-REFERENCE TO RELATED APPLICATIONS

The present application claims priority to Korean Patent Application No. 10-2016-0075630, entitled “ELECTRONIC DEVICE AND METHOD FOR FABRICATING THE SAME” and filed on Jun. 17, 2016, which is incorporated herein by reference in its entirety.

### TECHNICAL FIELD

This patent document relates to memory circuits or devices and their applications in electronic devices or systems.

### BACKGROUND

Recently, as electronic appliances trend toward miniaturization, low power consumption, high performance, multi-functionality, and so on, semiconductor devices capable of storing information in various electronic appliances such as a computer, a portable communication device, and so on have been demanded in the art, and research has been conducted for the semiconductor devices. Such semiconductor devices include semiconductor devices which can store data using a characteristic that they are switched between different resistant states according to an applied voltage or current, for example, an RRAM (resistive random access memory), a PRAM (phase change random access memory), an FRAM (ferroelectric random access memory), an MRAM (magnetic random access memory), an E-fuse, etc.

### SUMMARY

The disclosed technology in this patent document includes various implementations of an electronic device that has improved memory cell operation characteristics and improved reliability, and a method for fabricating the electronic device.

In an implementation, a method for fabricating an electronic device including a semiconductor memory includes: forming a memory layer over a substrate; forming a memory element by selectively etching the memory layer, wherein forming the memory element includes forming an etching residue on a sidewall of the memory element, the etching residue including a first metal; and forming a spacer by implanting oxygen and a second metal into the etching residue, the spacer including a compound of the first metal-oxygen-the second metal, the second metal being different from the first metal.

Implementations of the above method may include one or more the following.

The spacer is formed using an ion implantation process. Forming the spacer includes implanting the oxygen and the second metal into the etching residue at a slanted-angle direction, the slanted-angle direction forming an oblique angle with respect to an upper surface of the substrate. In the compound, a bonding force between the first metal and the oxygen is different from a bonding force between the second metal and the oxygen. The method further comprises: removing at least a portion of the spacer, after forming the spacer. Removing at least the portion of the spacer is performed using a chemical cleaning process. Removing at least the portion of the spacer is performed using a physical etch process that uses a neutral chemical species. Forming the memory element includes forming a hard mask pattern that includes the first metal over the memory layer, and wherein forming the spacer includes implanting the oxygen and the second metal into the hard mask pattern. The method further comprising: simultaneously removing at least a portion of the spacer and at least a portion of the hard mask pattern after the spacer is formed. The memory element includes a material having a variable resistance characteristic, the material being a metal oxide or a phase-change material. The memory element includes: a free layer having a changeable magnetization direction; a pinned layer having a fixed magnetization direction; and a tunnel barrier layer interposed between the free layer and the pinned layer. The method further comprises forming a contact plug over the substrate, the contact plug being disposed under the memory element, wherein the memory element overlaps with the contact plug, and the memory element has a lower surface that is smaller than an upper surface of the contact plug. The contact plug has a planarized upper surface. The contact plug includes the first metal. The spacer has an insulating property.

In another implementation, an electronic device includes: a semiconductor memory, which includes: a memory element; and a spacer disposed on a sidewall of the memory element, the spacer including a compound of a first metal-oxygen-a second metal, wherein the first metal and the second metal are different from each other.

Implementations of the above electronic device may include one or more the following.

In the compound, a bonding force between the first metal and the oxygen is different from a bonding force between the second metal and the oxygen. The memory element includes a material having a variable resistance characteristic, the material being a metal oxide or a phase-change material. The memory element includes: a free layer having a changeable magnetization direction; a pinned layer having a fixed magnetization direction; and a tunnel barrier layer interposed between the free layer and the pinned layer. The semiconductor memory further includes: a contact plug that is disposed under the memory element and that vertically overlaps with the memory element, the contact plug being coupled to the memory element, wherein an upper surface of the contact plug is larger than a lower surface of the memory element. The contact plug has a planarized upper surface. The contact plug includes the first metal. The spacer has an insulating property.

The electronic device may further include a microprocessor which includes: a control unit configured to receive a signal including a command from an outside of the microprocessor, and performs extracting, decoding of the command, or controlling input or output of a signal of the microprocessor; an operation unit configured to perform an operation based on a result that the control unit decodes the command; and a memory unit configured to store data for performing the operation, data corresponding to a result of performing the operation, or an address of data for which the operation is performed, wherein the semiconductor memory is part of the memory unit in the microprocessor.

The electronic device may further include a processor which includes: a core unit configured to perform, based on a command inputted from an outside of the processor, an operation corresponding to the command, by using data; a cache memory unit configured to store data for performing the operation, data corresponding to a result of performing the operation, or an address of data for which the operation is performed; and a bus interface connected between the core unit and the cache memory unit, and configured to transmit data between the core unit and the cache memory unit, wherein the semiconductor memory is part of the cache memory unit in the processor.

The electronic device may further include a processing system which includes: a processor configured to decode a command received by the processor and control an operation for information based on a result of decoding the command; an auxiliary memory device configured to store a program for decoding the command and the information; a main memory device configured to call and store the program and the information from the auxiliary memory device such that the processor can perform the operation using the program and the information when executing the program; and an interface device configured to perform communication between at least one of the processor, the auxiliary memory device and the main memory device and the outside, wherein the semiconductor memory is part of the auxiliary memory device or the main memory device in the processing system.

The electronic device may further include a data storage system which includes: a storage device configured to store data and conserve stored data regardless of power supply; a controller configured to control input and output of data to and from the storage device according to a command inputted form an outside; a temporary storage device configured to temporarily store data exchanged between the storage device and the outside; and an interface configured to perform communication between at least one of the storage device, the controller and the temporary storage device and the outside, wherein the semiconductor memory is part of the storage device or the temporary storage device in the data storage system.

The electronic device may further include a memory system which includes: a memory configured to store data and conserve stored data regardless of power supply; a memory controller configured to control input and output of data to and from the memory according to a command inputted form an outside; a buffer memory configured to buffer data exchanged between the memory and the outside; and an interface configured to perform communication between at least one of the memory, the memory controller and the buffer memory and the outside, wherein the semiconductor memory is part of the memory or the buffer memory in the memory system.

These and other aspects, implementations and associated advantages are described in greater detail in the drawings, the description and the claims.

### BRIEF DESCRIPTION OF THE DRAWINGS

FIGS. 1A to 1F illustrate a semiconductor memory and a method for fabricating the semiconductor memory in accordance with an implementation of the present disclosure.

FIG. 2 is a cross-sectional view illustrating a semiconductor memory in accordance with an implementation of the present disclosure.

FIGS. 3A to 3E are cross-sectional views illustrating a semiconductor memory and a method for fabricating the semiconductor memory in accordance with an implementation of the present disclosure.

FIG. 4 is an example of a configuration diagram of a microprocessor implementing memory circuitry based on the disclosed technology.

FIG. 5 is an example of a configuration diagram of a processor implementing memory circuitry based on the disclosed technology.

FIG. 6 is an example of a configuration diagram of a system implementing memory circuitry based on the disclosed technology.

FIG. 7 is an example of a configuration diagram of a data storage system implementing memory circuitry based on the disclosed technology.

FIG. 8 is an example of a configuration diagram of a memory system implementing memory circuitry based on the disclosed technology.

### DETAILED DESCRIPTION

Various examples and implementations of the disclosed technology are described below in detail with reference to the accompanying drawings.

The drawings may not be necessarily to scale and in some instances, proportions of at least some of structures in the drawings may have been exaggerated in order to clearly illustrate certain features of the described examples or implementations. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure may not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

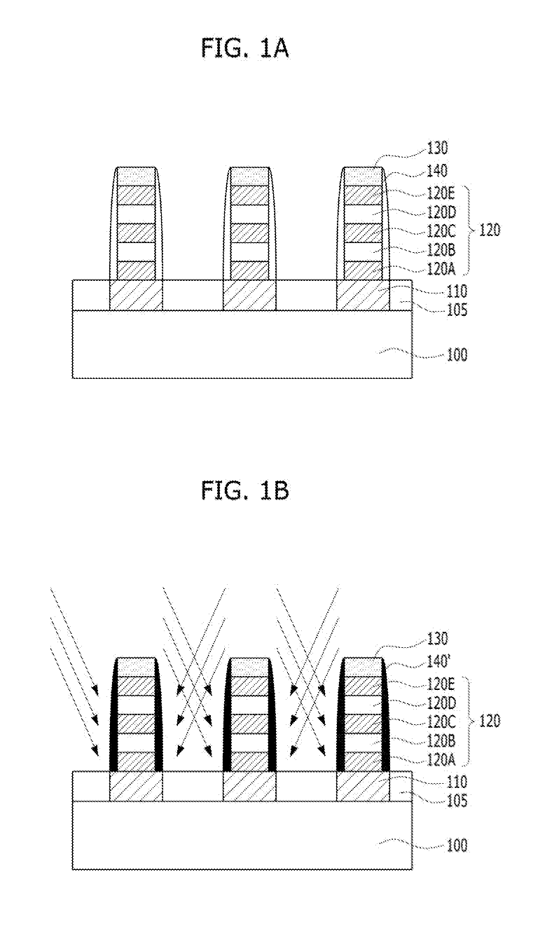

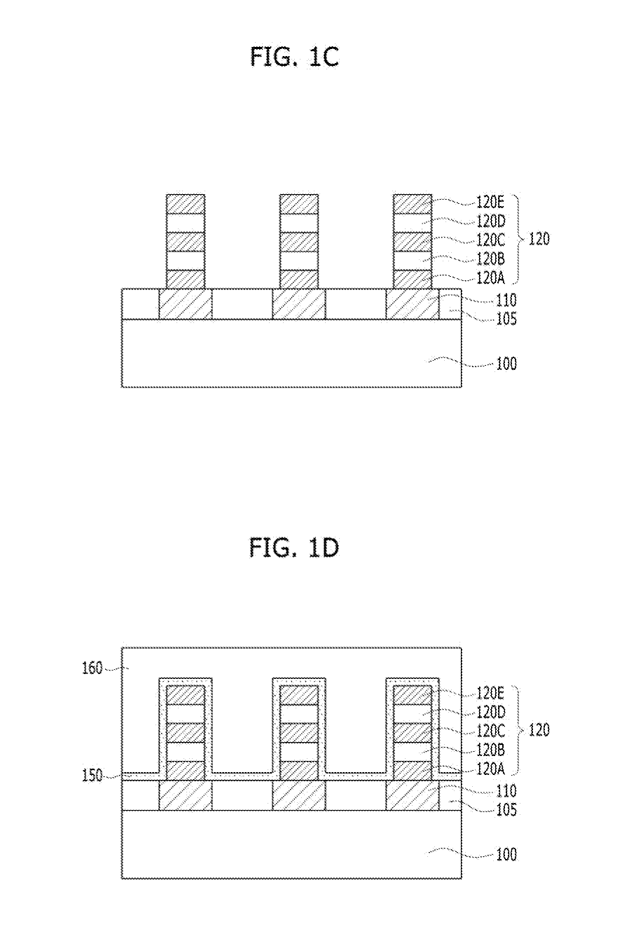

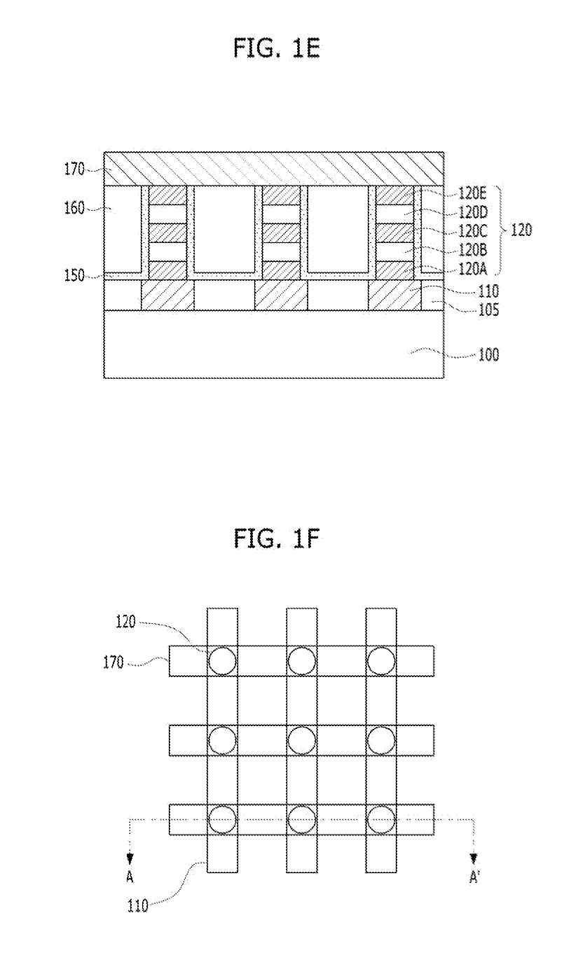

FIGS. 1A to 1F illustrate a semiconductor memory and a method for fabricating the semiconductor memory in accordance with an implementation of the present disclosure. FIGS. 1A to 1D are cross-sectional views describing intermediate processes for fabricating the semiconductor memory shown in FIGS. 1E and 1F. FIG. 1F is a plan view illustrating the semiconductor memory in accordance with an implementation of the present disclosure. FIG. 1E is a cross-sectional view obtained by cutting the semiconductor memory of FIG. 1F along a line A-A′.

A method for fabricating the semiconductor memory in accordance with an implementation of the present disclosure is described in accordance with FIGS. 1A to 1F.

Referring to FIG. 1A, a substrate 100, in which a predetermined required lower structure (not shown) is disposed, may be provided. For example, the lower structure may include transistors that control first lines 110 and/or second lines, e.g., 170 of FIGS. 1E and 1F, which are formed over the substrate 100.

Subsequently, a plurality of first lines 110 and a first inter-layer dielectric layer 105 may be formed over the substrate 100. The first lines 110 may extend in a first direction that intersects the line A-A′ of FIG. 1F. The first inter-layer dielectric layer 105 may fill spaces between the first lines 110.

The first lines 110 may have a single-layer structure or a multi-layer structure, and may include any of diverse conductive materials, such as metals, metal nitrides, and/or combinations thereof. The first inter-layer dielectric layer 105 may have a single-layer structure or a multi-layer structure, and may include any of diverse insulating materials, such as a silicon oxide, a silicon nitride, and/or a combination thereof. The first lines 110 may be formed by depositing a conductive material over the substrate 100 and selectively etching the conductive material, and then the first inter-layer dielectric layer 105 may be formed by filling the spaces between the first lines 110 with an insulating material. Alternatively, the first inter-layer dielectric layer 105 may be formed by depositing an insulating material over the substrate 100 and forming trenches in the insulating material by selectively etching the insulating material, and then the first lines 110 may be formed by filling the trenches with a conductive material.

Subsequently, memory cell structures 120 may be formed over the first lines 110. Each of the memory cell structures 120 may include a lower electrode 120A, a selection element 120B, an intermediate electrode 120C, a memory element 120D, and an upper electrode 120E, which are stacked over the first lines 110. When viewed from the perspective of a plan view, as shown in FIG. 1F, the memory cell structures 120 may be arranged in a matrix distributed in rows and columns extending along the first direction and along a second direction intersecting the first direction. The memory cell structures 120 may be disposed in intersection regions between the first lines 110 and second lines 170, which are described below. In the present implementation of the disclosure, each of the memory cell structures 120 may have a size that is equal to or smaller than each intersection region disposed between the first lines 110 and the second lines 170. According to an implementation of the present disclosure, each of the memory cell structures 120 may have a size that is larger than the intersection region disposed between the first lines 110 and the second lines 170. A hard mask pattern 130, which is used for patterning the memory cell structures 120 and has sidewalls aligned with the memory cell structure 120, may be disposed in an upper portion of each of the memory cell structures 120.

Herein, the lower electrode 120A may be disposed in a lower end of each memory cell structure 120, and may function as a transfer path for a current and/or a voltage that are supplied from the first line 110. The intermediate electrode 120C may be disposed between the selection element 120B and the memory element 120D, and may electrically connect the selection element 120B and the memory element 120D while physically separating the selection element 120B and the memory element 120D from each other. The upper electrode 120E may be disposed in an upper end of the memory cell structure 120, and may function as a transfer path for a current and/or a voltage that are supplied from the second line 170. Each of the lower electrode 120A, the intermediate electrode 120C, and the upper electrode 120E may have a single-layer structure or a multi-layer structure, and may include one or more different conductive materials, such as metals, metal nitrides, carbon, and/or combinations thereof.

The selection element 120B may control the access to the memory element 120D. The selection element B may have selection element characteristics, such that the selection element 120B may block current flow when a level of voltage or current applied to the selection element 120B is equal to or lower than a predetermined threshold value, and may allow current flow at a level that drastically surges in substantial proportion to the level of the applied voltage or current when the level of the applied voltage or current is higher than the predetermined threshold value. The selection element 120B may allow tunneling of electrons when a particular voltage or current is applied. The selection element 120B may be a Metal-Insulator-Transition (MIT) device, such as a device including NbO₂ and/or TiO₂; a Mixed Ion-Electron Conducting (MIEC) device, such as a device including ZrO₂(Y₂O₃), Bi₂O₃—BaO, and/or (La₂O₃)x(CeO₂)1−x; an Ovonic Threshold Switching (OTS) device including a chalcogenide-based material, such as Ge₂Sb₂Te₅, As₂Te₃, As₂, and/or As₂Se₃; or a tunneling dielectric layer that is formed of a thin film including one or more different insulating materials, e.g., a silicon oxide, a silicon nitride, a metal oxide, and the like. The selection element 120B may have a single-layer structure or a multi-layer structure, and may carry out the selection element characteristics with one layer or a combination of more than two layers.

A device capable of storing different data using one or more different methods may be used as the memory element 120D. For example, the memory element 120D may be a variable resistance device that stores data by switching between different resistance states according to a voltage or current applied to the memory element 120D. When the variable resistance device has a low resistance state, the variable resistance device may store, for example, a datum representing ‘1’. When the variable resistance device has a high resistance state, the variable resistance device may store, for example, a datum representing ‘0’. In the present implementation of the disclosure, the variable resistance device may include a transition metal oxide that could be used for an RRAM, a metal oxide such as a perovskite-based material, or a phase-change material such as a chalcogenide-based material that could be used for a PRAM. The variable resistance device may have a single-layer structure or a multi-layer structure, and may carry the variable resistance characteristics with one layer or a combination of more than two layers.

When an etch process is performed to form the memory cell structures 120, the hard mask patterns 130 may collectively function as an etch barrier. The hard mask patterns 130 may have a single-layer structure or a multi-layer structure, and may include one or more different materials, each of which has a different etch selectivity from the memory cell structures 120. The hard mask patterns 130 may include an insulating material or a conductive material, such as metal or a metal nitride.

In the present implementation, each of the memory cell structures 120 includes the lower electrode 120A, the selection element 120B, the intermediate electrode 120C, the memory element 120D, and the upper electrode 120E, which are sequentially stacked. However, the memory cell structures 120 may have different forms, as long as the memory cell structures 120 have data storing characteristics. For example, at least one of the lower electrode 120A, the intermediate electrode 120C, and the upper electrode 120E may be omitted, or the selection element 120B may be omitted. In an implementation, the positions of the selection element 120B and the memory element 120D may be switched with each other as compared to the positions shown in FIGS. 1A to 1E. Each memory cell structure 120 may include more than one layer (not shown) in addition to the layers 120A to 120E for improving the data storing characteristics of the memory cell structure 120 or for improving the fabrication process.

Constituents of the memory cell structures 120 (such as the lower electrode 120A, the selection element 120B, the intermediate electrode 120C, the memory element 120D, and the upper electrode 120E) may be formed by forming material layers over the first inter-layer dielectric layer 105 and the first lines 110 (such as a lower electrode layer, a selection element layer, an intermediate electrode layer, a memory element layer, and the upper electrode layer), forming the hard mask patterns 130 over the material layers, and then etching the material layers by using the hard mask patterns 130 as an etch barrier.

During the etch process, however, etching residue 140 may remain attached to the sidewalls of the memory cell structures 120 and the hard mask patterns 130. When at least one among the lower electrode 120A, the intermediate electrode 120C, the upper electrode 120E, and the hard mask pattern 130 includes a metal, the etching residue 140 may include the metal. If the etching residue 140 includes the metal or another highly conductive material, an undesirable flow of current may be caused due to the etching residue 140, which may lead to a malfunction of the memory cell structure 120. To prevent a malfunction due to the etching residue 140, the following processes of FIGS. 1B and 1C may be performed.

Referring to FIG. 1B, the etching residue 140 may be transformed into an insulating metal oxide by implanting oxygen elements and metal elements into the etching residue 140. The metal elements implanted into the etching residue 140 may be different from the metal elements that are already included in the etching residue 140. When the metal elements included in the etching residue 140 are first metal elements and the metal elements implanted into the etching residue 140 are second metal elements, the etching residue 140 may be transformed into insulating spacers 140′, which include a compound including the first metal element, oxygen, and the second metal element through the implantation process of FIG. 1B. That is, the insulating spacers 140′ may include a compound of the first metal element-oxygen-the second metal element. In the compound, oxygen elements may serve as bridges between the first metal elements and the second metal elements. Non-limiting examples of the second metal elements include transition metals, such as W, Ta, Ti, Hf, La, Zr, Fe, Cu, Ni, Co, Cr, Mn, and Zn, or other similar metals, such as Al.

The implantation of the oxygen elements and the second metal elements may be performed using an ion implantation method. Using ion implantation causes less damage to the memory cell structures 120 than a method using plasma.

Furthermore, the oxygen elements and the second metal elements may be implanted through an entire exposed surface of the etching residue 140. That is, the oxygen elements and the second metal elements may be implanted in a direction that is slanted at a predetermined angle, instead of a right angle, with respect to an upper surface of the substrate 100, in order to transform the entire etching residue 140 into the spacers 140′. That is, the oxygen elements and the second metal elements may be implanted in a direction that forms an oblique angle with respect to the upper surface of the substrate 100. The implantation at the slanted angle may be carried out by inclining the wafer in a chamber where the memory cell structures 120 and the hard mask patterns 130 are formed.

Meanwhile, although not illustrated, when the hard mask patterns 130 include the same metal elements as the first metal elements in the etching residue 140, the oxygen elements and the second metal elements may be implanted into the hard mask patterns 130 through the implantation process. As a result, the hard mask patterns 130 may be transformed into an insulating material that includes the same material as that of the spacers 140′, that is, the compound of the first metal-oxygen-second metal.

Referring to FIG. 1C, the spacers 140′ may be chemically or physically removed.

The process of chemically removing the spacers 140′ may include a wet cleaning process using a predetermined chemical or a dry-cleaning process using a predetermined gas. For this cleaning process, an alkali chemical or gas such as ammonia may be used; or an organic acid-based chemical or gas such as oxalic acid, tartaric acid, or citric acid may be used. Since the bonding forces between the oxygen elements and the first metal elements are different from the bonding forces between the oxygen elements and the second metal elements in the spacers 140′, partial polarization may occur in the compound of the first metal-oxygen-second metal. As a result, the reactivity of the compound in the spacers 140′ with the chemical or gas that is used for the cleaning process is greater than of an oxide of a single metal, for example, an oxide of the first metal element or second metal element, and thus, the spacers 140′ may be easily removed.

The process of physically removing the spacers 140′ may include an etch process using neutral chemical species, such as Ion Beam Etching (IBE). The neutral chemical species may include inert gas such as Argon (Ar) and/or Helium (He). Since the bonding forces between the oxygen elements and the first metal elements are different from the bonding forces between the oxygen elements and the second metal elements in the spacers 140′, the structure of the compound of the first metal, the oxygen, and the second metal may be spatially distorted. As a result of the distorted structure of the compound, the bonding forces between the oxygen elements and the first metal elements, and the bonding forces between the oxygen elements and the second metal elements, are weakened, and thus the spacers 140′ may be easily removed using the neutral chemical species.

When the spacers 140′ are easily removed, as described above, the cleaning process and/or the etch process do not need to be performed excessively. For example, the etch process may remove the spacers in a relatively short time. Therefore, damage affected on the memory cell structures 120 due to excessive cleaning or etching processes may be suppressed.

Meanwhile, when the hard mask patterns 130 are transformed into the same material as the spacers 140′, the hard mask patterns 130 may be removed together with the spacers 140′. On the other hand, when the hard mask patterns 130 are not transformed into the same material as the spacers 140′, a process for removing the hard mask patterns 130 may be performed in addition to the process for removing the spacers 140′.

Although FIG. 1C shows that the hard mask patterns 130 are completely removed, in an implementation, the hard mask patterns 130 may fully or partially remain according to the kind of process utilized to remove the spacers 140′. Subsequently, the hard mask patterns 130 may be fully removed in a subsequent process illustrated in FIG. 1E, which will be described in detail later.

Referring to FIG. 1D, a capping layer 150 for protecting the memory cell structures 120 may be formed over the profile of the resultant structure of FIG. 1C. If the hard mask patterns 130 are not completely removed and at least partially remain in the structure of FIG. 1C (not illustrated), the capping layer 150 may be formed over the profile of the sidewalls of the memory cell structures 120 as well as the sidewalls and upper surfaces of the hard mask patterns 130. The capping layer 150 may have a single-layer structure or a multi-layer structure, and may include an insulating material, such as a silicon nitride. In an implementation, the capping layer 150 may be omitted.

Subsequently, a second inter-layer dielectric layer 160 may be formed over the capping layer 150. The second inter-layer dielectric layer 160 may be formed to have a thickness that sufficiently fills a space between the memory cell structures 120, which are covered with the capping layer 150. The second inter-layer dielectric layer 160 may have a single-layer structure or a multi-layer structure, and may include any of diverse insulating materials, such as a silicon oxide, a silicon nitride, and/or a combination thereof.

Referring to FIG. 1E, a planarization process, e.g., a Chemical Mechanical Polishing (CMP) process, may be performed on the second inter-layer dielectric layer 160 and the capping layer 150 until upper surfaces of the memory cell structures 120 are exposed. When the hard mask patterns 130 are not fully removed with the spacers 140′ and thus the hard mask patterns 130 at least partially remain in the above-described structure of FIG. 1C, the remaining hard mask patterns 130 may be removed along with the second inter-layer dielectric layer 160 and the capping layer 150 by performing the planarization process until the upper surfaces of the memory cell structures 120 are exposed.

Subsequently, a plurality of second lines 170 and a third inter-layer dielectric layer (not shown) may be formed over the memory cell structures 120, the capping layer 150, and the second inter-layer dielectric layer 160. The plurality of second lines 170 may extend in the second direction intersecting the first direction, and may be coupled to the upper surfaces of the memory cell structures 120. The second direction may be parallel with the line A-A′ of FIG. 1F. The third inter-layer dielectric layer may fill spaces between the plurality of second lines 170.

Through the process described above, the semiconductor memory shown in FIGS. 1E and 1F may be fabricated.

Referring to FIGS. 1E and 1F, the memory cell structures 120 may be disposed inside intersection regions between the first lines 110, which extend in the first direction, and the second lines 170, which extend in the second direction. No metal material that may function as a path for current leakage may be present on the sidewalls of the memory cell structures 120 by removing the spacers 140′. In short, the sidewalls of the memory cell structures 120 may directly contact the capping layer 150 and/or the second inter-layer dielectric layer 160.

The memory cell structures 120 may store different data according to the voltage or current that is supplied thereto through the first lines 110 and the second lines 170. In particular, when the memory cell structures 120 include variable resistance elements, the memory cell structures 120 may store different data by switching between different resistance states.

According to the implementations described above, it is possible to block current leakage that occurs from the sidewalls of the memory cell structures 120 by implanting metal elements and oxygen elements into the conductive etching residue 140, which is formed on the sidewalls of the memory cell structures 120, thereby transforming the etching residue 140 into the insulating spacers 140′, and then removing the insulating spacers 140′. Since the metal elements implanted into the etching residue 140 are different from the metal elements included in the etching residue 140, the spacers 140′ may be formed to include a heterogeneous metal compound using the oxygen elements as bridges between the different metal elements. Since the heterogeneous metal compound may be easily removed chemically or physically, the spacers 140′ may be readily removed. For this reason, an excessive etching process or an excessive cleaning process does not need to be performed, and damage affected on the memory cell structures 120 due to the etching or cleaning processes may be prevented or decreased.

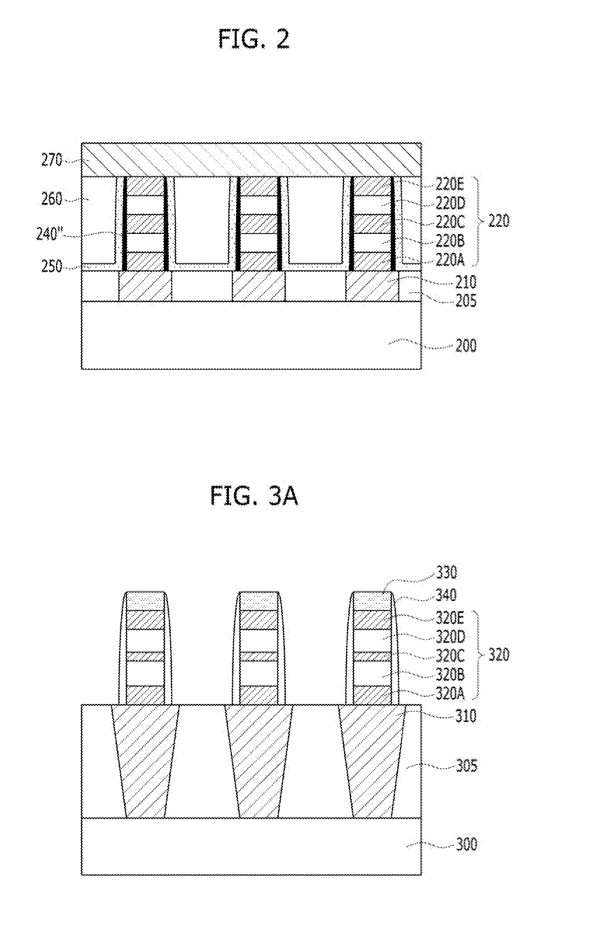

Meanwhile, although the spacers 140′ may be completely removed in certain implementations of the present disclosure, the spacers 140′ may only be partially removed according to a process in an implementation of the present disclosure. Since the spacers 140′ have an insulating property, the spacers 140′ may remain on the sidewalls of the memory cell structures 120 without causing a problem. This will be described below by referring to an example illustrated in FIG. 2.

FIG. 2 is a cross-sectional view illustrating a semiconductor memory in accordance with an implementation of the present disclosure. Only the differences between the implementation illustrated in FIG. 2 and the implementation illustrated in FIGS. 1A to 1F are described, and a description of the same features is omitted.

Referring to FIG. 2, after the processes to form the structures of FIGS. 1A and 1B, the process to form the structure of FIG. 1C is performed. In the implementation illustrated in FIG. 2, the spacers may not be completely removed and may partially or fully remain after the process to form the structure of FIG. 1C. This may be because, for example, a process for removing the spacers is omitted or performed insufficiently. The partially or fully remaining spacers 240″ are illustrated in FIG. 2. Subsequently, the processes used to form the structures of FIGS. 1D and 1E may be performed on the structure including the partially or fully remaining spacer 240″.

As a result of the process used to form the structure of FIG. 2, first lines 210 extending in the first direction and second lines 270 extending in the second direction may be formed over a substrate 200. A first inter-layer dielectric layer 205 may be disposed between the first lines 210. Memory cell structures 220 may be formed at the cross points between the first lines 210 and the second lines 270. Each of the memory cell structures 220 may include a lower electrode 220A, a selection element 220B, an intermediate electrode 220C, a memory element 220D, and an upper electrode 220E, which are stacked.

The remaining spacers 240″ may include a first metal element-oxygen-second metal element compound on the sidewalls of the memory cell structures 220. The spacers 240″ may be as thick as or may be thinner than the spacers 140′, which are described with reference to FIG. 1B.

A capping layer 250 may be formed along the profile of the spacers 240″.

A second inter-layer dielectric layer 260 may be disposed between the memory cell structures 220 that are covered with the capping layer 250.

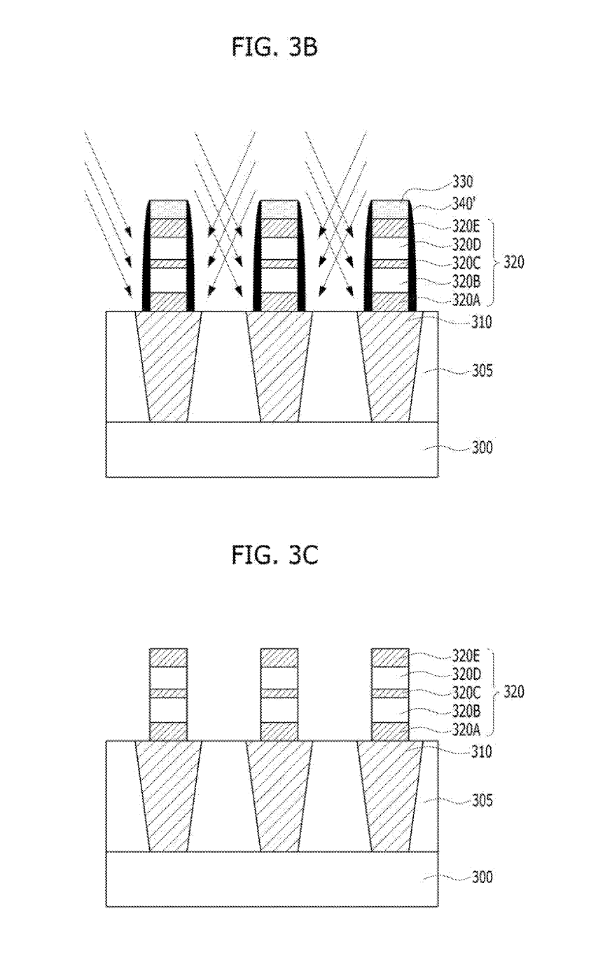

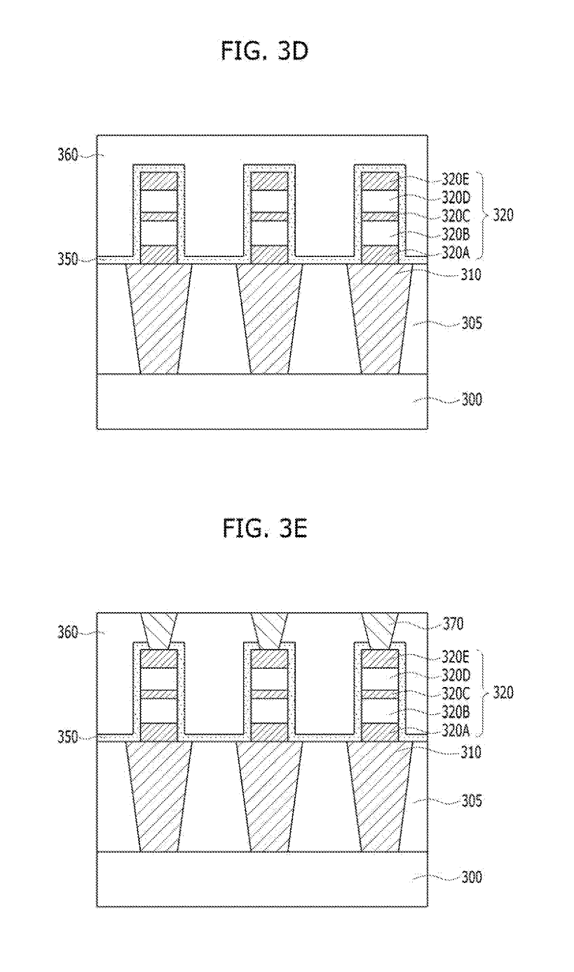

Meanwhile, the implementations described above show a case in which each of the memory cell structures include a selection element and a memory element, and are formed at a cross point between two intersecting lines, but there may be other implementations according to the kind of the semiconductor memory desired. For example, the selection element and the memory element may be formed separately, which will be described below with reference to FIGS. 3A to 3E.

FIGS. 3A to 3E are cross-sectional views illustrating a semiconductor memory and a method for fabricating the semiconductor memory in accordance with an implementation of the present disclosure. Only the differences between the structures illustrated by FIGS. 3A to 3E and the structures illustrated by FIGS. 1A to 1E and tare described, and a description of the same features is omitted.

Referring to FIG. 3A, a substrate 300, including a predetermined required lower structure (not shown), may be provided. For example, the lower structure (not shown) may include a selection element that controls access to a memory element 320. Non-limiting examples of the selection element may include a transistor and a diode.

Subsequently, a first inter-layer dielectric layer 305 and lower contact plugs 310 may be formed over the substrate 300. The first inter-layer dielectric layer 305 may include any of diverse insulating materials, such as a silicon oxide, a silicon nitride, and/or a combination thereof. The lower contact plugs 310 may penetrate through the first inter-layer dielectric layer 305. The lower contact plugs 310 may be disposed under the memory elements 320, and may serve as paths through which a current or voltage is supplied to the memory elements 320. The upper ends of the lower contact plugs 310 may be coupled to the memory elements 320, and the lower ends of the lower contact plugs 310 may be coupled to the selection element of the substrate 300. The lower contact plugs 310 may include a metal material, for example, a metal nitride, such as TiN, WN, TaN, or the like, or combinations thereof. The lower contact plugs 310 may be formed by selectively etching the first inter-layer dielectric layer 305 so as to form holes that expose a portion of the substrate 300, depositing a conductive material in a thickness that may sufficiently fill the holes over the profile of the substrate structure, and performing a planarization process, e.g., a CMP process, until the upper surface of the first inter-layer dielectric layer 305 is exposed. As a result, the lower contact plugs 310 may have planar upper surfaces.

Subsequently, the memory elements 320, which are coupled to the lower contact plugs 310, may be formed over the lower contact plugs 310. Herein, each of the memory elements 320 may have a stacked structure including a lower electrode 320A; a Magnetic Tunnel Junction (MTJ) structure including a free layer 320B, a tunnel barrier layer 320C, and a pinned layer 320D; and an upper electrode 320E. Hard mask patterns 330 that are used for patterning the memory elements 320 and that have sidewalls aligned with the memory elements 320 may be disposed on top of the memory elements 320.

The lower electrode 320A may be disposed in the lowermost part of each memory element 320, and may couple the lower contact plug 310 to the memory element 320. The lower electrode 320A may also help a layer disposed over the lower electrode 320A grow into a target crystal structure. The lower electrode 320A may include any of diverse conductive materials, such as metals and/or metal nitrides.

The free layer 320B of the MTJ structure includes a first ferromagnetic material and has a changeable magnetization direction. The pinned layer 320D of the MTJ structure includes a second ferromagnetic material and has a fixed magnetization direction. The tunnel barrier layer 320C of the MTJ structure is interposed between the free layer 320B and the pinned layer 320D. In an implementation, the positions of the free layer 320B and the pinned layer 320D may be switched with each other. That is, the free layer 320B may be under the tunnel barrier layer 320C and the pinned layer 320D may be above the tunnel barrier layer 320C, or the free layer 320B may be above the tunnel barrier layer 320C and the pinned layer 320D may be under the tunnel barrier layer 320C.

Since the free layer 320B may store different data according to the magnetization direction of the first ferromagnetic material, the free layer 320B may be referred to as a storage layer. The magnetization direction of the pinned layer 320D does not change, unlike the magnetization direction of the free layer 320B. The pinned layer 320D may be referred to as a reference layer. Each of the free layer 320B and the pinned layer 320D may have a single-layer structure or a multi-layer structure, and may include a ferromagnetic material, such as any of a Fe—Pt alloy, a Fe—Pd alloy, a Co—Pd alloy, a Co—Pt alloy, a Co—Fe alloy, a Fe—Ni—Pt alloy, a Co—Fe—Pt alloy, a Co—Ni—Pt alloy, a Co—Fe—B alloy, and the like.

The tunnel barrier layer 320C may change the magnetization direction of the free layer 320B by tunneling electrons into the free layer 320B during a data write operation of the memory element 320. The tunnel barrier layer 320C may have a single-layer structure or a multi-layer structure, and may include an oxide, such as any of Al₂O₃, MgO, CaO, SrO, TiO, VO, NbO, and the like.

The upper electrode 320E may be disposed in the uppermost part of each memory element 320, and may couple an upper contact plug disposed over the upper electrode 320E to the memory element 320. The upper electrode 320E may include any of diverse conductive materials, such as metals and/or metal nitrides.

The hard mask patterns 330 may function as an etch barrier during an etch process used to form the memory elements 320. The hard mask patterns 330 may have a single-layer structure or a multi-layer structure, and may include any of diverse materials that each have a different etch selectivity from the memory elements 320. The hard mask patterns 330 may include an insulating material or a conductive material, such as a metal or a metal nitride.

In the present implementation of the disclosure, the memory elements 320 may further include one or more layers (not shown) for improving the characteristics of the memory elements 320 or for improving the fabrication process.

Also, in the present implementation of the disclosure, each memory element 320 may be smaller than each lower contact plug 310, so that the entire lower surface of the memory element 320 may be disposed over the upper surface of the lower contact plug 310. Accordingly, the MTJ structure, which includes the free layer 320B, the tunnel barrier layer 320C, and a pinned layer 320D, may be prevented from being disposed on the border between the lower contact plugs 310 and the first inter-layer dielectric layer 305, and therefore the MTJ structure may be prevented from being bent. If the MTJ structure is disposed on the border between the lower contact plug 310 and the first inter-layer dielectric layer 305, and thus bent, the characteristics of the memory element 320 may be deteriorated. For example, when the tunnel barrier layer 320C is formed over a surface whose planarity is poor, and the tunnel barrier layer 320C is thus bent, the characteristics of the MTJ structure may be deteriorated due to the Neel Coupling effect.

The memory elements 320 may be formed by forming material layers over the first inter-layer dielectric layer 305 and the lower contact plugs 310, forming the hard mask patterns 330 over the material layers, and etching the material layers by using the hard mask patterns 330 as the etch barrier. During the etch process, however, etching residue 340 may remain attached to the sidewalls of the memory elements 320 and the hard mask patterns 330. When the memory elements 320 and/or the hard mask patterns 330 include a metal, the etching residue 340 may also include the metal. Furthermore, when the size of each memory element 320 is smaller than the size of each lower contact plug 310, and thus the upper surfaces of the lower contact plugs 310 are exposed, a metal included in the lower contact plugs 310 may be attached to the sidewalls of the memory elements 320. In short, the etching residue 340 may include the metal that is included in the lower contact plugs 310. If the etching residue 340 includes a highly conductive material, an undesirable flow of current may be caused due to the etching residue 340, which may lead to a malfunction of the memory elements 320. To prevent the malfunction, the following processes of FIGS. 3B and 3C may be performed.

Referring to FIG. 3B, the etching residue 340 may be transformed into spacers 340′ including an insulating metal oxide by implanting oxygen atoms and metal element atoms into the etching residue 340. When the metal element atoms included in the etching residue 340 are first metal element atoms and the metal elements implanted into the etching residue 340 are second metal element atoms, the etching residue 340 may be transformed into the insulating spacers 340′, which include a compound of the first metal element-oxygen-the second metal element through the implantation process of FIG. 3B.

Furthermore, when the hard mask patterns 330 include the first metal element, which is the same material as that of the etching residue 340, the oxygen atoms and the second metal element atoms may be implanted into the hard mask patterns 330 as well through the process of implanting the oxygen atoms and the second metal element atoms into the etching residue 340. Thus, the hard mask patterns 330 may also be transformed into an insulating material including the compound of the first metal element-oxygen-the second metal element.

Referring to FIG. 3C, the spacers 340′ may be removed chemically or physically. The hard mask patterns 330 may be removed along with the spacers 340′, or the hard mask patterns 330 may be removed in a separate process.

Although the spacers 340′ are completely removed in the present implementation of the disclosure, the concept and spirit of the present disclosure are not so limited. Although not illustrated, the spacers 340′ may entirely or partly remain on the sidewalls of the memory elements 320.

Referring to FIG. 3D, a capping layer 350 for protecting the memory elements 320 may be formed over the profile of the resultant structure of FIG. 3C.

Subsequently, a second inter-layer dielectric layer 360 may be formed over the capping layer 350, and may have a thickness that fills the spaces between the memory elements 320 covered by the capping layer 350. The second inter-layer dielectric layer 360 may have a planarized surface. To this end, a planarization process may be additionally performed after the second inter-layer dielectric layer 360 is formed.

Referring to FIG. 3E, upper contact plugs 370 may be formed. The upper contact plugs 370 may penetrate through the second inter-layer dielectric layer 360 and the capping layer 350, and may be coupled to the upper surfaces of the memory elements 320. The upper contact plugs 370 may be disposed over the memory elements 320, and may provide a path for supplying a current or voltage to the memory elements 320. The lower ends of the upper contact plugs 370 are coupled to the memory elements 320, and the upper ends of the upper contact plugs 370 are coupled to predetermined lines (not shown). The upper contact plugs 370 may include a metal, such as Ti and/or W; a metal nitride, such as TiN, WN, and/or TaN; and/or combinations thereof. The upper contact plugs 370 may be formed by selectively etching the second inter-layer dielectric layer 360 and the capping layer 350, so as to form holes that expose the upper surfaces of the upper electrodes 320E; depositing a conductive material on the resultant structure in a thickness that sufficiently fills the holes; and performing an etch-back process or a CMP process on the conductive material until the upper surface of the second inter-layer dielectric layer 360 is exposed.

Using the processes described above, the semiconductor memory shown in FIG. 3E may be fabricated.

According to the implementations of the present disclosure, operation characteristics of memory cells and reliability of the memory cells may be improved by the semiconductor memory described above and by the method for fabricating the semiconductor memory described above.

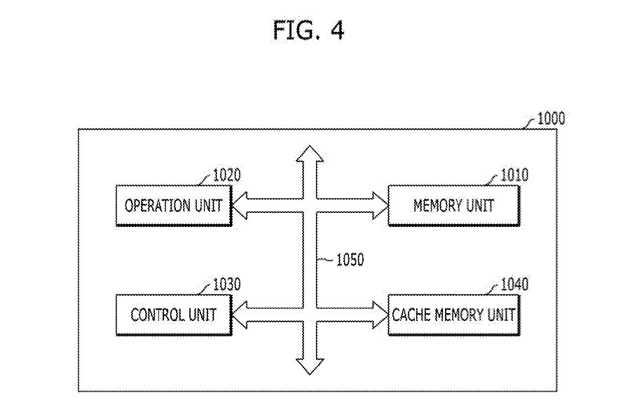

The above and other memory circuits or semiconductor devices based on the disclosed technology can be used in a range of devices or systems. FIGS. 4-8 provide some examples of devices or systems that can implement the memory circuits disclosed herein.

FIG. 4 is an example of configuration diagram of a microprocessor implementing memory circuitry based on the disclosed technology.

Referring to FIG. 4, a microprocessor 1000 may perform tasks for controlling and tuning a series of processes of receiving data from various external devices, processing the data, and outputting processing results to external devices. The microprocessor 1000 may include a memory unit 1010, an operation unit 1020, a control unit 1030, a cache memory unit 1040, and so on. The microprocessor 1000 may be any of various data processing units such as a central processing unit (CPU), a graphic processing unit (GPU), a digital signal processor (DSP), and an application processor (AP).

The memory unit 1010 may store data in the microprocessor 1000, as a processor register, register, or the like. The memory unit 1010 may include a data register, an address register, a floating point register, and so on. The memory unit 1010 may include any of various registers. The memory unit 1010 may perform a function of temporarily storing data for which operations are to be performed by the operation unit 1020, result data of performing the operations, and addresses where data for performing of the operations are stored.

The memory unit 1010 may include one or more of the above-described semiconductor devices in accordance with implementations of the present disclosure. For example, the memory unit 1010 may include a memory element; and a spacer disposed on a sidewall of the memory element, the spacer including a compound of a first metal-oxygen-a second metal, wherein the first metal and the second metal are different from each other. Accordingly, operating characteristics and reliability of the memory unit 1010 may be improved. As a consequence, operating characteristics and reliability of the microprocessor 1000 may be improved.

The operation unit 1020 may perform four arithmetical operations or logical operations according to results of the control unit 1030 decoding commands. The operation unit 1020 may include at least one arithmetic logic unit (ALU) and so on.

The control unit 1030 may receive signals from the memory unit 1010, the operation unit 1020, and an external device from the microprocessor 1000, extract, decode commands, control input and output of signals of the microprocessor 1000, and execute processing represented by programs.

The microprocessor 1000 according to the present implementation may additionally include a cache memory unit 1040 which can temporarily store data to be inputted from an external device other than the memory unit 1010 or to be outputted to an external device. In this case, the cache memory unit 1040 may exchange data with the memory unit 1010, the operation unit 1020 and the control unit 1030 through a bus interface 1050.

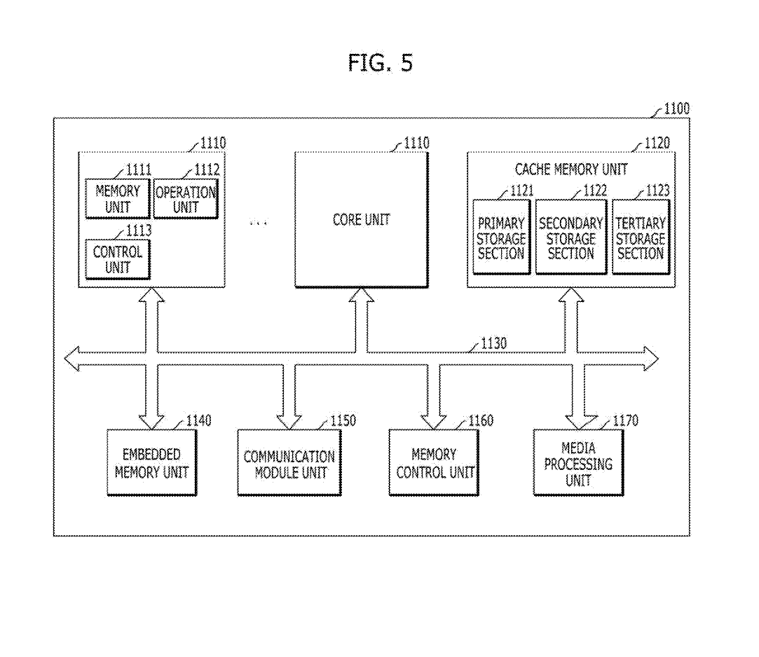

FIG. 5 is an example of configuration diagram of a processor implementing memory circuitry based on the disclosed technology.

Referring to FIG. 5, a processor 1100 may improve performance and realize multi-functionality by including various functions other than those of a microprocessor, which performs tasks for controlling and tuning a series of processes of receiving data from various external devices, processing the data, and outputting processing results to external devices. The processor 1100 may include a core unit 1110, which serves as the microprocessor, a cache memory unit 1120, which serves to store data temporarily, and a bus interface 1130, which transfers data between internal and external devices. The processor 1100 may include various system-on-chips (SoCs) such as a multi-core processor, a graphic processing unit (GPU), and/or an application processor (AP).

The core unit 1110 of the present implementation is a part that performs arithmetic logic operations for data inputted from an external device, and may include a memory unit 1111, an operation unit 1112, and a control unit 1113.

The memory unit 1111 is a part that stores data in the processor 1100, as a processor register, a register, or the like. The memory unit 1111 may include a data register, an address register, a floating point register, and so on. Besides, the memory unit 1111 may include various registers. The memory unit 1111 may perform a function of temporarily storing data for which operations are to be performed by the operation unit 1112, result data of performing the operations, and addresses where data for performing of the operations are stored. The operation unit 1112 is a part that performs operations in the processor 1100. The operation unit 1112 may perform four arithmetical operations or logical operations, according to results that the control unit 1113 decodes commands, or the like. The operation unit 1112 may include at least one arithmetic logic unit (ALU) and so on. The control unit 1113 may receive signals from the memory unit 1111, the operation unit 1112, and an external device of the processor 1100, perform extraction, decoding of commands, controlling input and output of signals of processor 1100, and execute processing represented by programs.

The cache memory unit 1120 is a part that temporarily stores data to compensate for a difference in data processing speed between the core unit 1110 operating at a high speed and an external device operating at a low speed. The cache memory unit 1120 may include a primary storage section 1121, a secondary storage section 1122, and a tertiary storage section 1123. In general, the cache memory unit 1120 includes the primary and secondary storage sections 1121 and 1122, and may include the tertiary storage section 1123 in a case where high storage capacity is required. As the occasion demands, the cache memory unit 1120 may include an increased number of storage sections. That is to say, the number of storage sections that are included in the cache memory unit 1120 may be changed according to a design. The speeds at which the primary, secondary and tertiary storage sections 1121, 1122, and 1123 store and discriminate data may be the same or different. In the case where the speeds of the respective storage sections 1121, 1122, and 1123 are different, the speed of the primary storage section 1121 may be the largest. At least one storage section of the primary storage section 1121, the secondary storage section 1122 and the tertiary storage section 1123 of the cache memory unit 1120 may include one or more of the above-described semiconductor devices in accordance with implementations of the present disclosure. For example, the cache memory unit 1120 may include a memory element; and a spacer disposed on a sidewall of the memory element, the spacer including a compound of a first metal-oxygen-a second metal, wherein the first metal and the second metal are different from each other. Accordingly, operating characteristics and reliability of the cache memory unit 1120 may be improved. As a consequence, operating characteristics and reliability of the processor 1100 may be improved.

Although it is shown in FIG. 5 that all the primary, secondary, and tertiary storage sections 1121, 1122, and 1123 are configured inside the cache memory unit 1120, it is to be noted that all the primary, secondary and tertiary storage sections 1121, 1122, and 1123 of the cache memory unit 1120 may be configured outside the core unit 1110, and may compensate for a difference in data processing speed between the core unit 1110 and the external device. Meanwhile, it is to be noted that the primary storage section 1121 of the cache memory unit 1120 may be disposed inside the core unit 1110 and the secondary storage section 1122, and that the tertiary storage section 1123 may be configured outside the core unit 1110 to strengthen a function of compensating for a difference in data processing speed. In another implementation, the primary and secondary storage sections 1121 and 1122 may be disposed inside the core units 1110 and tertiary storage sections 1123 may be disposed outside core units 1110.

The bus interface 1130 is a part that connects the core unit 1110, the cache memory unit 1120 and external device, and that allows data to be efficiently transmitted.

The processor 1100 according to the present implementation may include a plurality of core units 1110, and the plurality of core units 1110 may share the cache memory unit 1120. The plurality of core units 1110 and the cache memory unit 1120 may be directly connected or may be connected through the bus interface 1130. The plurality of core units 1110 may be configured in the same way as the above-described configuration of the core unit 1110. In the case where the processor 1100 includes the plurality of core unit 1110, the primary storage section 1121 of the cache memory unit 1120 may be configured in each core unit 1110 in correspondence to the number of the plurality of core units 1110, and the secondary storage section 1122 and the tertiary storage section 1123 may be configured outside the plurality of core units 1110 in such a way as to be shared through the bus interface 1130. The processing speed of the primary storage section 1121 may be larger than the processing speeds of the secondary and tertiary storage section 1122 and 1123. In another implementation, the primary storage section 1121 and the secondary storage section 1122 may be configured in each core unit 1110 in correspondence to the number of the plurality of core units 1110, and the tertiary storage section 1123 may be configured outside the plurality of core units 1110 in such a way as to be shared through the bus interface 1130.

The processor 1100 according to the present implementation may further include an embedded memory unit 1140, which stores data, a communication module unit 1150, which can transmit and receive data to and from an external device in a wired or wireless manner, a memory control unit 1160, which drives an external memory device, and a media processing unit 1170, which processes the data processed in the processor 1100 or the data inputted from an external input device and outputs the processed data to an external interface device and so on. Additionally, the processor 1100 may include a plurality of various modules and devices. In this case, the plurality of modules that are added may exchange data with the core units 1110 and the cache memory unit 1120 and with one another, through the bus interface 1130.

The embedded memory unit 1140 may include not only a volatile memory but also a nonvolatile memory. The volatile memory may include a DRAM (dynamic random access memory), a mobile DRAM, an SRAM (static random access memory), a memory with similar functions to above mentioned memories, and so on. The nonvolatile memory may include any of a ROM (read only memory), a NOR flash memory, a NAND flash memory, a phase change random access memory (PRAM), a resistive random access memory (RRAM), a spin transfer torque random access memory (STTRAM), a magnetic random access memory (MRAM), and a memory with similar functions.

The communication module unit 1150 may include a module capable of being connected with a wired network, a module capable of being connected with a wireless network, or, or both. The wired network module may include a local area network (LAN), a universal serial bus (USB), an Ethernet, power line communication (PLC) such as various devices that send and receive data through transmit lines, and so on. The wireless network module may include a device using any of Infrared Data Association (IrDA), code division multiple access (CDMA), time division multiple access (TDMA), frequency division multiple access (FDMA), a wireless LAN, Zigbee, a ubiquitous sensor network (USN), Bluetooth, radio frequency identification (RFID), long term evolution (LTE), near field communication (NFC), a wireless broadband Internet (Wibro), high speed downlink packet access (HSDPA), wideband CDMA (WCDMA), ultra wideband (UWB) such as various devices that send and receive data without transmit lines, and so on.

The memory control unit 1160 is to administrate and process data transmitted between the processor 1100 and an external storage device operating according to a different communication standard. The memory control unit 1160 may include various memory controllers, for example, devices that may control IDE (Integrated Device Electronics), SATA (Serial Advanced Technology Attachment), SCSI (Small Computer System Interface), RAID (Redundant Array of Independent Disks), an SSD (solid state disk), eSATA (External SATA), PCMCIA (Personal Computer Memory Card International Association), a USB (universal serial bus), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The media processing unit 1170 may process the data processed in the processor 1100 or the data inputted in the forms of image, voice, and others, from the external input device and output the data to the external interface device. The media processing unit 1170 may include a graphic processing unit (GPU), a digital signal processor (DSP), a high definition audio device (HD audio), a high definition multimedia interface (HDMI) controller, and so on.

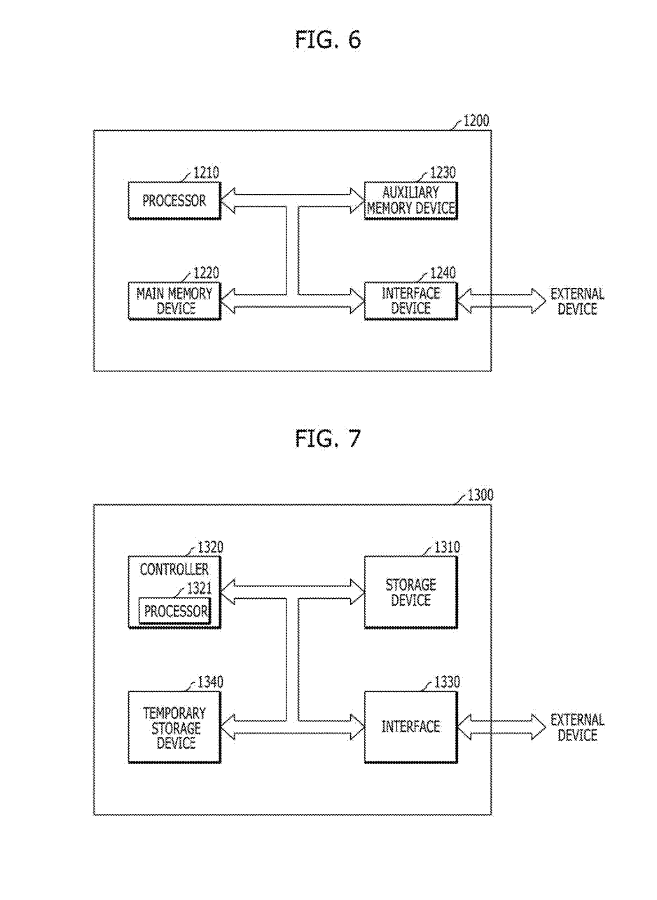

FIG. 6 is an example of configuration diagram of a system implementing memory circuitry based on the disclosed technology.

Referring to FIG. 6, a system 1200 as an apparatus for processing data may perform inputting, processing, outputting, communicating, storing, etc., to conduct a series of manipulations for data. The system 1200 may include a processor 1210, a main memory device 1220, an auxiliary memory device 1230, an interface device 1240, and so on. The system 1200 of the present implementation may be any of various electronic systems that operate using processors, such as a computer, a server, a PDA (personal digital assistant), a portable computer, a web tablet, a wireless phone, a mobile phone, a smart phone, a digital music player, a PMP (portable multimedia player), a camera, a global positioning system (GPS), a video camera, a voice recorder, a telematics, an audio visual (AV) system, a smart television, and so on.

The processor 1210 may decode inputted commands and processes, operate, compare, etc., for the data stored in the system 1200, and may control these operations. The processor 1210 may include a microprocessor unit (MPU), a central processing unit (CPU), a single/multi-core processor, a graphic processing unit (GPU), an application processor (AP), a digital signal processor (DSP), and so on.

The main memory device 1220 is a storage, which can temporarily store, call and execute program codes or data from the auxiliary memory device 1230 when programs are executed, and which can conserve memorized contents even when power supply is cut off. The main memory device 1220 may include one or more of the above-described semiconductor devices in accordance with implementations of the present disclosure. For example, the main memory device 1220 may include a memory element; and a spacer disposed on a sidewall of the memory element, the spacer including a compound of a first metal-oxygen-a second metal, wherein the first metal and the second metal are different from each other. Accordingly, operating characteristics and reliability of the main memory device 1220 may be improved. As a consequence, operating characteristics and reliability of the system 1200 may be improved.

Also, the main memory device 1220 may further include any of a static random access memory (SRAM), a dynamic random access memory (DRAM), and so on, and may be of a volatile memory type in which all contents are erased when power supply is cut off. In contrast, the main memory device 1220 may not include the semiconductor devices according to implementations of the present disclosure, but may include any of a static random access memory (SRAM), a dynamic random access memory (DRAM), and so on, and may be of a volatile memory type in which all contents are erased when power supply is cut off.

The auxiliary memory device 1230 is a memory device for storing program codes or data. While the speed of the auxiliary memory device 1230 is slower than the main memory device 1220, the auxiliary memory device 1230 can store a larger amount of data. The auxiliary memory device 1230 may include one or more of the above-described semiconductor devices in accordance with implementations of the present disclosure. For example, the auxiliary memory device 1230 may include a memory element; and a spacer disposed on a sidewall of the memory element, the spacer including a compound of a first metal-oxygen-a second metal, wherein the first metal and the second metal are different from each other. Accordingly, operating characteristics and reliability of the auxiliary memory device 1230 may be improved. As a consequence, operating characteristics and reliability of the system 1200 may be improved.

Also, the auxiliary memory device 1230 may further include a data storage system (see the reference numeral 1300 of FIG. 7) such as any of a magnetic tape that uses magnetism, a magnetic disk, a laser disk that uses optics, a magneto-optical disc that uses both magnetism and optics, a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on. In contrast, the auxiliary memory device 1230 may not include the semiconductor devices according to implementations of the present disclosure, but may include data storage systems (see the reference numeral 1300 of FIG. 7) such as a magnetic tape using magnetism, a magnetic disk, a laser disk using optics, a magneto-optical disc using both magnetism and optics, a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The interface device 1240 may perform an exchange of commands and data between the system 1200 of the present implementation and an external device. The interface device 1240 may be any of a keypad, a keyboard, a mouse, a speaker, a mike, a display, various human interface devices (HIDs), a communication device, and so on. The communication device may include a module capable of being connected with a wired network, a module capable of being connected with a wireless network, or both. The wired network module may include any of a local area network (LAN), a universal serial bus (USB), an Ethernet, power line communication (PLC), such as various devices that send and receive data through transmit lines, and so on. The wireless network module may include a device using any of Infrared Data Association (IrDA), code division multiple access (CDMA), time division multiple access (TDMA), frequency division multiple access (FDMA), a wireless LAN, Zigbee, a ubiquitous sensor network (USN), Bluetooth, radio frequency identification (RFID), long term evolution (LTE), near field communication (NFC), a wireless broadband Internet (Wibro), high speed downlink packet access (HSDPA), wideband CDMA (WCDMA), ultra wideband (UWB), such as various devices which send and receive data without transmit lines, and so on.

FIG. 7 is an example of configuration diagram of a data storage system implementing memory circuitry based on the disclosed technology.

Referring to FIG. 7, a data storage system 1300 may include a storage device 1310 that has a nonvolatile characteristic as a component for storing data, a controller 1320 that controls the storage device 1310, an interface 1330 for connection with an external device, and a temporary storage device 1340 for storing data temporarily. The data storage system 1300 may be a disk type such as any of a hard disk drive (HDD), a compact disc read only memory (CDROM), a digital versatile disc (DVD), a solid state disk (SSD), and so on, and a card type such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The storage device 1310 may include a nonvolatile memory, which stores data semi-permanently. The nonvolatile memory may include any of a ROM (read only memory), a NOR flash memory, a NAND flash memory, a phase change random access memory (PRAM), a resistive random access memory (RRAM), a magnetic random access memory (MRAM), and so on.

The controller 1320 may control exchange of data between the storage device 1310 and the interface 1330. To this end, the controller 1320 may include a processor 1321 for performing an operation of processing commands that are inputted through the interface 1330 from an outside of the data storage system 1300, and so on.

The interface 1330 is to perform exchange of commands and data between the data storage system 1300 and the external device. In the case where the data storage system 1300 is a card type, the interface 1330 may be compatible with interfaces that are used in any of various devices, such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on; or may be compatible with interfaces that are used in devices similar to the above mentioned devices. In the case where the data storage system 1300 is a disk type, the interface 1330 may be compatible with interfaces, such as any of IDE (Integrated Device Electronics), SATA (Serial Advanced Technology Attachment), SCSI (Small Computer System Interface), eSATA (External SATA), PCMCIA (Personal Computer Memory Card International Association), a USB (universal serial bus), and so on; or may be compatible with the interfaces that are similar to the above mentioned interfaces. The interface 1330 may be compatible with one or more interfaces having a different type from each other.

The temporary storage device 1340 can store data temporarily for efficiently transferring data between the interface 1330 and the storage device 1310 according to diversifications and high performance of an interface with an external device, a controller, and a system. The temporary storage device 1340 for temporarily storing data may include one or more of the above-described semiconductor devices in accordance with implementations of the present disclosure. The temporary storage device 1340 may include a memory element; and a spacer disposed on a sidewall of the memory element, the spacer including a compound of a first metal-oxygen-a second metal, wherein the first metal and the second metal are different from each other. Accordingly, operating characteristics and reliability of the temporary storage device 1340 may be improved. As a consequence, operating characteristics and reliability of the data storage system 1300 may be improved.

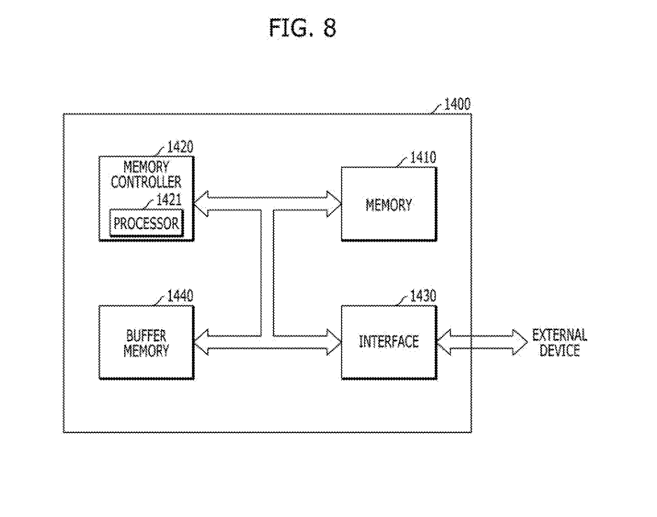

FIG. 8 is an example of configuration diagram of a memory system implementing memory circuitry based on the disclosed technology.

Referring to FIG. 8, a memory system 1400 may include any of a memory 1410, which has a nonvolatile characteristic, as a component for storing data; a memory controller 1420, which controls the memory 1410; an interface 1430 for connection with an external device; and so on. The memory system 1400 may be a card type such as any of a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The memory 1410 for storing data may include one or more of the above-described semiconductor devices in accordance with implementations of the present disclosure. For example, the memory 1410 may include a memory element and a spacer disposed on a sidewall of the memory element, and the spacer may include a compound of a first metal-oxygen-second metal, wherein the first metal and the second metal are different from each other. Accordingly, operating characteristics and reliability of the memory 1410 may be improved. As a consequence, operating characteristics and reliability of the memory system 1400 may be improved.

Also, the memory 1410 according to the present implementation may further include any of a ROM (read only memory), a NOR flash memory, a NAND flash memory, a phase change random access memory (PRAM), a resistive random access memory (RRAM), a magnetic random access memory (MRAM), and so on, which each have a nonvolatile characteristic.

The memory controller 1420 may control an exchange of data between the memory 1410 and the interface 1430. To this end, the memory controller 1420 may include a processor 1421 for performing an operation for producing information and processing commands inputted through the interface 1430 from an outside of the memory system 1400.

The interface 1430 is to perform an exchange of commands and data between the memory system 1400 and the external device. The interface 1430 may be compatible with interfaces that are used in devices, such as any of a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on; or may be compatible with interfaces that are used in devices similar to the above mentioned devices. The interface 1430 may be compatible with one or more interfaces having a different type from each other.

The memory system 1400 according to the present implementation may further include any of a buffer memory 1440 for efficiently transferring data between the interface 1430 and the memory 1410 according to diversification and high performance of an interface with an external device, a memory controller, and a memory system. For example, the buffer memory 1440 for temporarily storing data may include one or more of the above-described semiconductor devices in accordance with implementations of the present disclosure. The buffer memory 1440 may include a memory element; and a spacer disposed on a sidewall of the memory element, the spacer including a compound of a first metal-oxygen-a second metal, wherein the first metal and the second metal are different from each other. Accordingly, operating characteristics and reliability of the buffer memory 1440 may be improved. As a consequence, operating characteristics and reliability of the memory system 1400 may be improved.

Moreover, the buffer memory 1440 according to the present implementation may further include any of an SRAM (static random access memory), a DRAM (dynamic random access memory), and so on, which have a volatile characteristic, and a phase change random access memory (PRAM), a resistive random access memory (RRAM), a spin transfer torque random access memory (STTRAM), a magnetic random access memory (MRAM), and so on, which each have a nonvolatile characteristic. In contrast, the buffer memory 1440 may not include the semiconductor devices according to implementations of the present disclosure, but may include any of an SRAM (static random access memory), a DRAM (dynamic random access memory), and so on, which have a volatile characteristic, and a phase change random access memory (PRAM), a resistive random access memory (RRAM), a spin transfer torque random access memory (STTRAM), a magnetic random access memory (MRAM), and so on, which have a nonvolatile characteristic.

Features in the above examples of electronic devices or systems in FIGS. 4-8 based on the memory devices disclosed in this document may be implemented in various devices, systems, or applications. Some examples include mobile phones or other portable communication devices, tablet computers, notebook or laptop computers, game machines, smart TV sets, TV set top boxes, multimedia servers, digital cameras with or without wireless communication functions, wrist watches, or other wearable devices with wireless communication capabilities.

While this patent document contains many specifics, these should not be construed as limitations on the scope of any of what may be claimed, but rather as descriptions of features that may be specific to particular embodiments of the disclosure. Certain features that are described in this patent document in the context of separate embodiments can also be implemented in combination in a single embodiment. Conversely, various features that are described in the context of a single embodiment can also be implemented in multiple embodiments separately, or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described. Other implementations, enhancements and variations can be made based on what is described and illustrated in this patent document.

What is claimed is:

1. A method for fabricating an electronic device including a semiconductor memory, the method comprising:
forming a memory layer over a substrate;
forming a memory element by selectively etching the memory layer, wherein forming the memory element includes forming an etching residue on a sidewall of the memory element, the etching residue including a first metal; and
forming a spacer by implanting oxygen and a second metal into the etching residue, the spacer including a compound of the first metal-oxygen-the second metal, the second metal being different from the first metal.

2. The method according to claim 1, wherein the spacer is formed using an ion implantation process.

3. The method according to claim 1, wherein forming the spacer includes implanting the oxygen and the second metal into the etching residue at a slanted-angle direction, the slanted-angle direction forming an oblique angle with respect to an upper surface of the substrate.

4. The method according to claim 1, wherein, in the compound, a bonding force between the first metal and the oxygen is different from a bonding force between the second metal and the oxygen.

5. The method according to claim 1, further comprising:
removing at least a portion of the spacer, after forming the spacer.

6. The method according to claim 5, wherein removing at least the portion of the spacer is performed using a chemical cleaning process.

7. The method according to claim 5, wherein removing at least the portion of the spacer is performed using a physical etch process that uses a neutral chemical species.

8. The method according to claim 1, wherein forming the memory element includes forming a hard mask pattern that includes the first metal over the memory layer, and
wherein forming the spacer includes implanting the oxygen and the second metal into the hard mask pattern.

9. The method according to claim 8, further comprising:
simultaneously removing at least a portion of the spacer and at least a portion of the hard mask pattern after the spacer is formed.

10. The method according to claim 1, wherein the memory element includes a material having a variable resistance characteristic.

11. The method according to claim 1, wherein the spacer has an insulating property.

12. An electronic device, comprising:
a semiconductor memory, which includes:
a memory element; and
a spacer disposed on a sidewall of the memory element, the spacer including a compound of a first metal-oxygen-a second metal,
wherein the first metal and the second metal are different from each other.

13. The electronic device according to claim 12, wherein, in the compound, a bonding force between the first metal and the oxygen is different from a bonding force between the second metal and the oxygen.

14. The electronic device according to claim 12, wherein the memory element includes a material having a variable resistance characteristic.

15. The electronic device according to claim 12, wherein the spacer has an insulating property.

16. The electronic device according to claim 12, further comprising a microprocessor that includes:
a control unit configured to receive a signal including a command from an external device, and to perform extracting, decoding of the command, or controlling an input or an output of a signal of the microprocessor;
an operation unit configured to perform an operation based on a result that the control unit decodes from the command; and
a memory unit configured to store any of data for performing the operation, data corresponding to a result of performing the operation, and an address of data for which the operation is performed,
wherein the semiconductor memory is part of the memory unit in the microprocessor.

17. The electronic device according to claim 12, further comprising a processor that includes:
a core unit configured to perform, based on a command inputted from an outside of the processor, an operation corresponding to the command by using data;
a cache memory unit configured to store any of data for performing the operation, data corresponding to a result of performing the operation, and an address of data for which the operation is performed; and
a bus interface connected between the core unit and the cache memory unit, and configured to transmit data between the core unit and the cache memory unit,
wherein the semiconductor memory is part of the cache memory unit in the processor.

18. The electronic device according to claim 12, further comprising a processing system that includes:
a processor configured to decode a command received by the processor and to control an operation for producing information based on a result of decoding the command; an auxiliary memory device configured to store a program for decoding the command and the information;
a main memory device configured to call and store the program and the information from the auxiliary memory device for the processor, the processor performing the operation using the program called by the main memory device and accessing the information stored in the main memory device when executing the program; and
an interface device configured to perform communication between an external device and at least one of the processor, the auxiliary memory device, and the main memory device,
wherein the semiconductor memory is part of the auxiliary memory device or the main memory device in the processing system.

19. The electronic device according to claim 12, further comprising a data storage system that includes:
a storage device configured to store data and to conserve stored data regardless of power supply;
a controller configured to control input and output of data to and from the storage device according to a command inputted from an external device;
a temporary storage device configured to temporarily store data exchanged between the storage device and the external device; and
an interface configured to perform communication between the external device and at least one of the storage device, the controller, and the temporary storage device,
wherein the semiconductor memory is part of the storage device or the temporary storage device in the data storage system.

20. The electronic device according to claim 12, further comprising a memory system that includes:
a memory configured to store data and to conserve stored data regardless of power supply;
a memory controller configured to control input and output of data to and from the memory according to a command inputted from an external device;
a buffer memory configured to buffer data exchanged between the memory and the external device; and
an interface configured to perform communication between the external device and at least one of the memory, the memory controller and the buffer memory,
wherein the semiconductor memory is part of the memory or the buffer memory in the memory system.
